(19) United States
(12) Patent Application Publication
(10) Pub. No.: US 2024/0282647 A1
(43) Pub. Date: Aug. 22, 2024

(54) CLUSTERED IC DIES TO INCREASE IC DIES PER WAFER

(71) Applicant: GlobalFoundries U.S. Inc., Malta, NY (US)

(72) Inventors: Laszlo Andras Fürst, Dresden (DE); Ulrich Zeiske, Coswig (DE); Georg Gnüchtel, Dresden (DE)

(21) Appl. No.: 18/171,729

(22) Filed: Feb. 21, 2023

(51) Int. Cl. H01L 21/66; G03F 1/44; G03F 1/70

(52) U.S. Cl. CPC H01L 22/34; G03F 1/44; G03F 1/70

(57) ABSTRACT

A reticle includes a body having a single-use illumination field. The single-use illumination field defines a layer including: a plurality of integrated circuit (IC) die clusters, each of the plurality of IC die clusters including a plurality of IC dies separated by a first scribe line having a first width. The plurality of IC die clusters are arranged in juxtaposition on the body and are separated by a second scribe line having a second width larger than the first width. The IC die clusters each have a same number of IC dies and a same area. There may be a different number of IC dies in an X direction than in a Y direction. The wider scribe lines are configured to include all optical or electrical test structures, and minimize effective die area. A wafer formed using the reticle and a method of forming the reticle are also provided.

### BACKGROUND

The present disclosure relates to integrated circuit (IC) dies and, more particularly, to an approach to a reticle setup, and semiconductor wafer fabrication using the reticle, that employs clustered dies to increase the number of IC dies per wafer.

Numerous IC dies or chips are formed on a single semiconductor wafer and then diced into separate chips. Producing as many good dies per wafer (GDPW) as possible requires maximizing the area used to produce IC dies. One limiting factor on maximizing GDPW is that optical and/or electrical test structures must be provided on the wafer to evaluate the IC chips prior to dicing. In one approach, the test structures are positioned in the scribe lines in various locations across the wafer. Scribe lines are sacrificial linear segments in the wafer that dictate where the IC chips are separated, e.g., by a plasma cutter, blade or laser. The dicing removes and/or destroys the test structures. The test structures are not located in all of the scribe lines across the entirety of the wafer, but the scribe lines have a consistent width across the wafer based on a required size for the test structures. Thus, the resulting scribe line area is significantly more than that required for the test structures, leaving unused space for IC chips and reducing GDPW. In a “structure-free scribe line (SFSL)” or “steal die” approach, rather than use the scribe lines, the locations of a number of IC chips are sacrificed for exclusive use for test structures. This approach prevents accurate across-reticle characterization, significantly reduces GDPW and is not scalable.

### SUMMARY

All aspects, examples and features mentioned below can be combined in any technically possible way.

An aspect of the disclosure provides a reticle, comprising: a body having a single-use illumination field defined therein, the single-use illumination field defining a layer including: a plurality of integrated circuit (IC) die clusters, each of the plurality of IC die clusters including a plurality of IC dies separated by a first scribe line having a first width, wherein the plurality of IC die clusters are arranged in juxtaposition on the body and are separated by a second scribe line having a second width larger than the first width, and wherein the plurality of IC die clusters each have a same number of IC dies and a same area.

An aspect of the disclosure provides a method, comprising: generating a plurality of reticle setups, each reticle setup representing a single-use reticle field arrangement and addressing a given set of design rules, each reticle setup defining a layer including: a plurality of integrated circuit (IC) die clusters, each of the plurality of IC die clusters including a plurality of IC dies separated by a scribe line having a first width, wherein the plurality of IC die clusters are arranged in juxtaposition to one another and are separated by a second scribe line having a second width larger than the first width, and wherein the plurality of IC die clusters each have a same number of IC dies and a same area, and a different number of IC dies in an X direction than in a Y direction; and fabricating a reticle including the reticle setup of the plurality of reticle setups having a smallest effective die area.

An aspect of the disclosure provides a semiconductor wafer, comprising: a plurality of integrated circuit (IC) die clusters, each of the plurality of IC die clusters including a plurality of IC dies separated by a first scribe line having a first width, wherein the plurality of IC die clusters are arranged in juxtaposition and are separated by a second scribe line having a second width larger than the first width, and wherein the plurality of IC die clusters each have a same number of IC dies and a same area, and a different number of IC dies in an X direction than in a Y direction.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1A shows a top-down view of a field of a conventional reticle;

FIG. 1B shows a schematic top-down of the reticle in FIG. 1A including test structures therein;

FIG. 2 shows a top-down view of a field of another conventional reticle;

FIG. 3 shows a top-down view of a semiconductor wafer formed using reticles as in FIG. 1A-B or 2;

FIG. 4 shows a top-down view of a field of a single-use reticle according to embodiments of the disclosure;

FIG. 5 shows a top-down view of a semiconductor wafer formed using reticles according to embodiments of the disclosure; and

FIG. 6 shows a flow diagram of a method according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a reticle including a body having a single-use illumination field. The single-use illumination field defines a layer including a plurality of integrated circuit (IC) die clusters. Each of the plurality of IC die clusters includes a plurality of IC dies separated by a first scribe line having a first width. The plurality of IC die clusters are arranged in juxtaposition on the body and are separated by a second scribe line having a second width larger than the first width. Each of the plurality of IC die clusters have the same number of IC dies and the same area. The IC die clusters may also have a different number of IC dies in an X direction than in a Y direction. The IC die clusters are configured to include all optical or electrical test structures in the wider scribe lines to minimize effective die area and increase good dies per wafer (GDPW). A wafer formed using the reticle and a method of forming the reticle are also provided. The reticle can be used to form a semiconductor wafer with increased GDPW. The semiconductor wafer with increased good dies is manufacturable without compromising quality, e.g., in terms of across reticle characterization, contamination-free manufacturing (CFM) die-to-die comparison, etc. The clustered die approach described herein is also scalable.

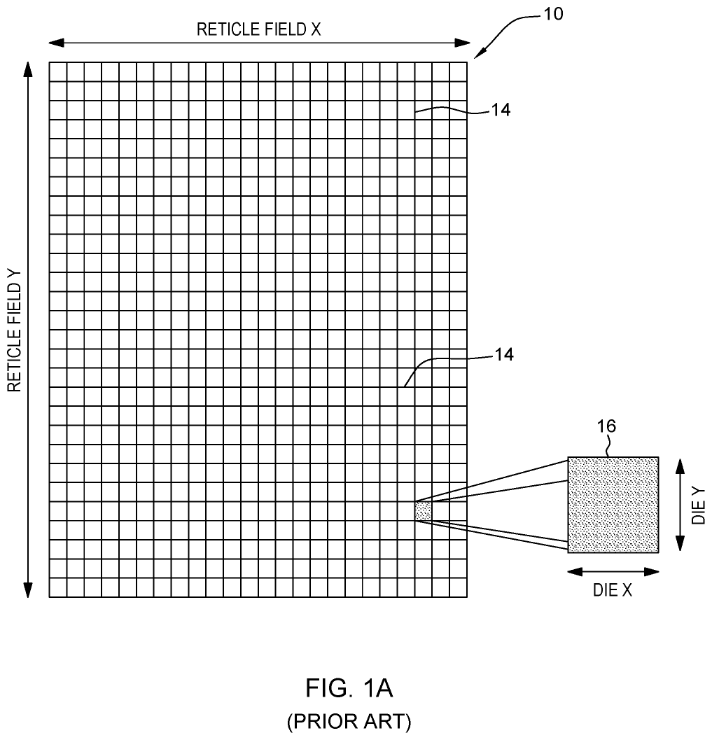

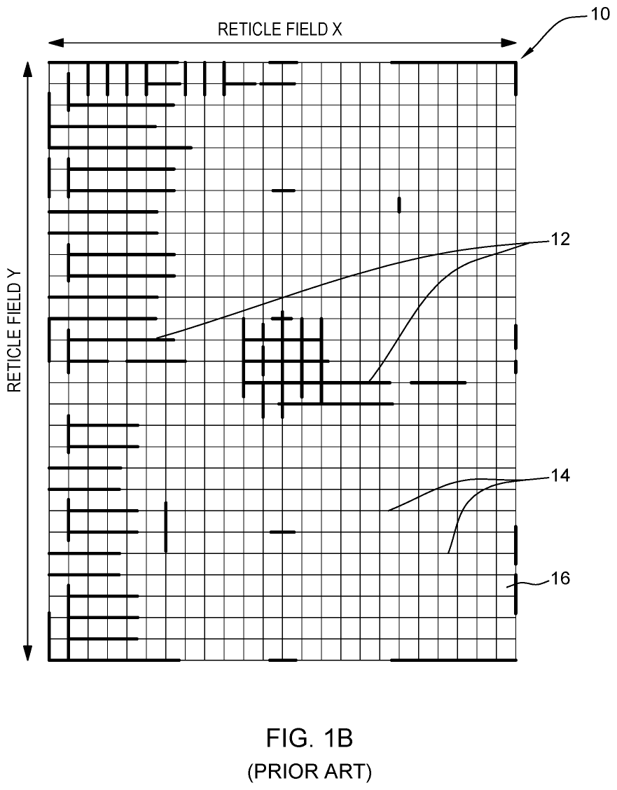

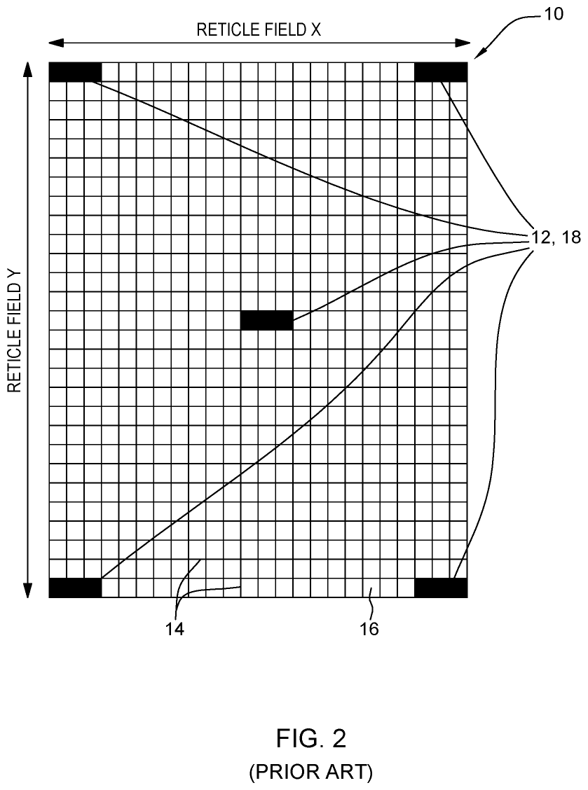

FIGS. 1A-B show top-down views of the same conventional reticle 10 in which optical and/or electrical test structures 12 (hereafter “test structures 12”) are positioned in scribe lines 14 of the reticle. More particularly, FIG. 1A shows scribe lines 14 and FIG. 1B shows a schematic view of test structures 12 (darker, thicker lines) in scribe lines 14. As shown in FIG. 1A, all scribe lines 14 have the same dimensions, e.g., width and depth, to accommodate any size test structure 12 wherever located on reticle 10. However, as shown in FIG. 1B, test structures 12 are usually not used in all scribe lines 14 on reticle 10. Rather, they are used only where needed. As a result, the area of scribe lines 14 is significantly more than required for test structure 12, leaving unused, wasted space for good IC dies 16. FIG. 2 shows a top-down view of another conventional reticle 10 in which test structures 12 are positioned in sacrificed, test IC dies 18 of the reticle. FIG. 2 shows a “structure-free scribe line (SFSL)” or “steal die” approach. Sacrificial IC dies 18 are only placed in certain locations on reticle 10 and thus this approach is not scalable and does not provide across-reticle characterization, e.g., providing the necessary areal distribution of the test structures within the reticle field for higher-order overlay compensation. Due to the sacrificing of IC dies 18 for test structures, this approach also significantly reduces GDPW.

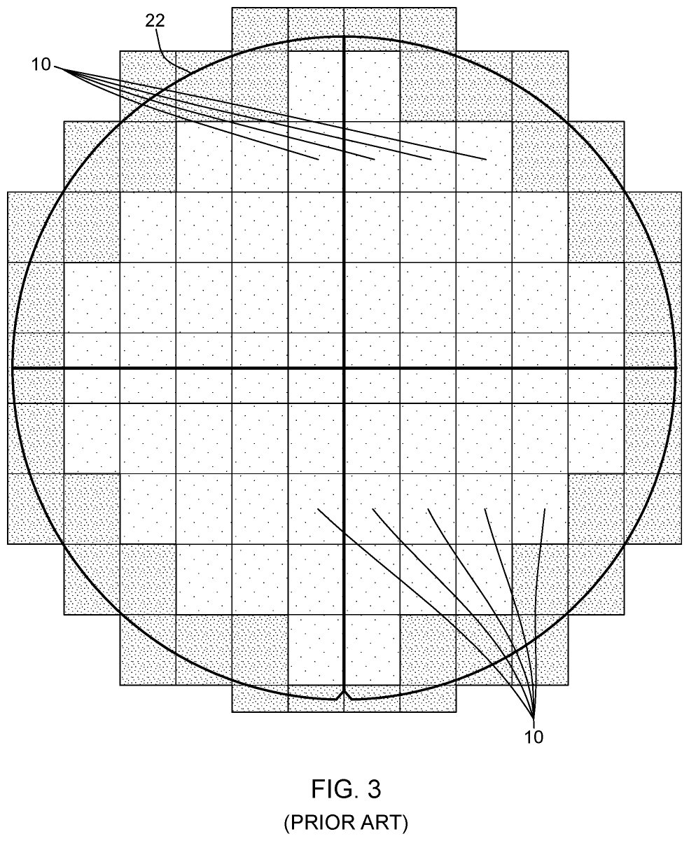

FIG. 3 shows a top-down view of application of reticles 10 from FIGS. 1A-B and 2 to a semiconductor wafer 22. As illustrated in FIG. 3, reticles 10 are multiple-use reticles that are stepped and exposed multiple times across a given semiconductor wafer 22, which magnifies the shortcomings of these approaches.

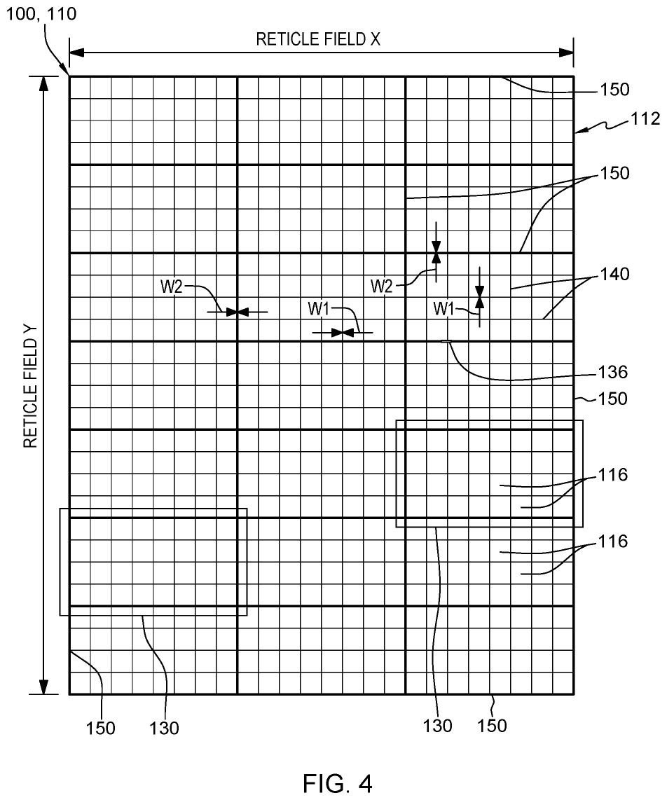

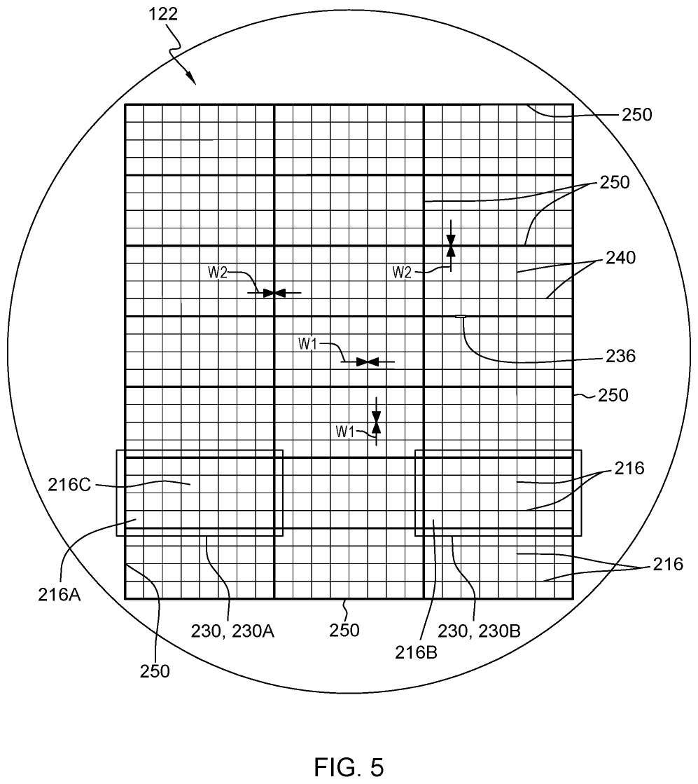

FIG. 4 shows a reticle 100, and FIG. 5 shows a semiconductor wafer 122 formed using reticles 100, according to embodiments of the disclosure.

Reticle 100 includes a body 110 having a single-use illumination field 112 defined therein. Body 110 and patterning thereon may be of any now known or later developed format, e.g., chrome on glass (COG), opaque molybdenum-silicon on glass (Opaque MoSi on Glass).

Single-use illumination field 112 includes an entirety of the field of reticle 100 for one or more semiconductor wafer 122 layers to which it is applied, so stepping and repetitive imaging is required. Single-use illumination field 112 defines a layer to form parts of IC dies 116 in a semiconductor wafer 122, e.g., defining a mask or parts of IC dies 116. The layer may include a plurality of integrated circuit (IC) die clusters 130 (only two labeled on FIG. 4). Each of plurality of IC die clusters 130 include (patterns for forming) a plurality of IC dies 116 separated by a first scribe line 140 having a first width W1. That is, IC dies 116 within a given IC die cluster 130 are separated by first scribe lines 140 having first width W1. First scribe lines 140 extend in both X and Y directions. IC die clusters 130 each have a same number of IC dies 116 and a same area. However, IC die clusters 130 may have a different number of IC dies 116 in an X direction than in a Y direction. In the non-limiting example shown in FIG. 4, each IC die cluster includes eight (8) IC dies 116 in an X direction, and four IC dies (4) in a Y direction. Hence, each IC die cluster 130 includes thirty-two (32) IC dies 116 and has an area that is thirty two times (32×) the area of each IC die 116 plus the area of the narrower first scribe lines 140 (see below).

IC die clusters 130 are arranged in juxtaposition on body 110 and are separated by a second scribe line 150 having a second width W2 larger than first width W1. First scribe lines 140 extend in both X and Y directions. Scribe lines 140, 150 may cross each other, where desired. Second width W2 of second scribe lines 150 and its area in X and Y directions are sized to accommodate any optical and/or electrical test structures 136 (hereafter “test structures 136”), while first width W1 of first scribe lines 140 are typically too small to accommodate test structures 136. Hence, test structures 136 are located within second scribe lines 150, but not first scribe lines 140. That is, the layer of single-use illumination field 112 includes the relevant parts of test structure 136 for a given layer in an area of second scribe line 150, and first scribe lines 140 are devoid of any test structures 136 therein. Second scribe line 150 extends around each of plurality of IC die clusters 130 individually. As shown in FIG. 4, second scribe line 150 also extends around collectively all of plurality of IC die clusters 130, around an outer periphery of single-use illumination field 112.

In certain embodiments, as shown in FIG. 4, plurality of die clusters 130 may include at least three IC die clusters 130 in an X direction, and may have a different number of IC die clusters 130 in a Y direction. In the non-limiting example shown in FIG. 4, reticle 100 includes three (3) die clusters 130 in the X direction, and seven die clusters 130 in the Y direction, forming a 3×7 arrangement of IC die clusters 130. Other arrangements having at least three in the X direction and may have a different number in the Y direction are also possible, e.g., 3×5, 5×9, 5×8, 5×9, etc.

One test structure 136 is shown enlarged with a dashed box for illustration purposes in FIG. 4. It will be recognized, however, that test structures 136 are wholly within second scribe lines 150 and do not interfere with IC dies 116 beyond the extent necessary to test the desired optical or electrical characteristics. Test structures 136 may include any now known or later developed optical test component and/or electrical circuitry for testing IC dies 116.

FIG. 5 shows a top-down view of a semiconductor wafer 122 formed using a plurality of reticles 100 for different layers of IC dies 216, according to embodiments of the disclosure. Plurality of reticles 100 including scribe lines 240, 250 and test structures 236 in wider scribe lines 250, as described herein, are used to form semiconductor wafer 122 using any now known or later developed semiconductor fabrication techniques. Semiconductor wafer 122 thus includes the same scribe lines 240, 250, allowing IC dies 216 therein to be diced from semiconductor wafer 122. The dicing process may using different width cutting devices for the different width scribe lines 240, 250. The dicing process(es) may include any now known or later developed dicing technique, e.g., plasma cutting, blades, laser, etc.

Prior to dicing, semiconductor wafer 122 includes a plurality of IC die clusters 230. Each of the plurality of IC die clusters 230 includes a plurality of (completed) IC dies 216 separated by a first scribe line 240 having first width W1. Plurality of IC die clusters 230 are arranged in juxtaposition and are separated by second scribe line 250 having second width W2 larger than first width W1. IC die clusters 230 have a different number of IC dies 216 in an X direction than in a Y direction and each of plurality of IC die clusters 230 have the same area with the same number of IC dies 116. Scribe lines 240, 250 may cross each other, where necessary. Second width W2 of second scribe lines 250 and their area in X and Y directions are sufficient to accommodate any (completed) test structures 236, while first width W1 of first scribe lines 240 is typically too small to accommodate test structures 236. Hence, test structures 236 are located within second scribe lines 250, but not first scribe lines 240. Second scribe line 250 extends individually around each IC die cluster of plurality 230 individually. As shown in FIG. 5, second scribe line 250 also extends around collectively all of plurality of IC die clusters 230.

In certain embodiments, as shown in FIG. 5, plurality of IC die clusters 230 may include at least three IC die clusters 230 in an X direction, and a different number of IC die clusters 230 in a Y direction. In the non-limiting example shown in FIG. 5, semiconductor wafer 122 includes three (3) die clusters 230 in the X direction, and seven die clusters 230 in the Y direction, forming a 3×7 arrangement of IC die clusters 230. As noted, other arrangements having at least three in the X direction and a different number in the Y direction are also possible, e.g., 3×5, 3×9, 4×7, 5×9, etc.

One schematic test structure 236 is shown enlarged with a dashed box for illustration purposes in FIG. 5. It will be recognized, however, that test structures 236 are wholly within second scribe lines 250 and do not interfere with completed IC dies 216 beyond the extent necessary to test the desired optical or electrical characteristics. Test structures 236 may include any now known or later developed optic test component and/or electrical circuitry for testing IC dies 216, and may be removed during dicing in a known fashion.

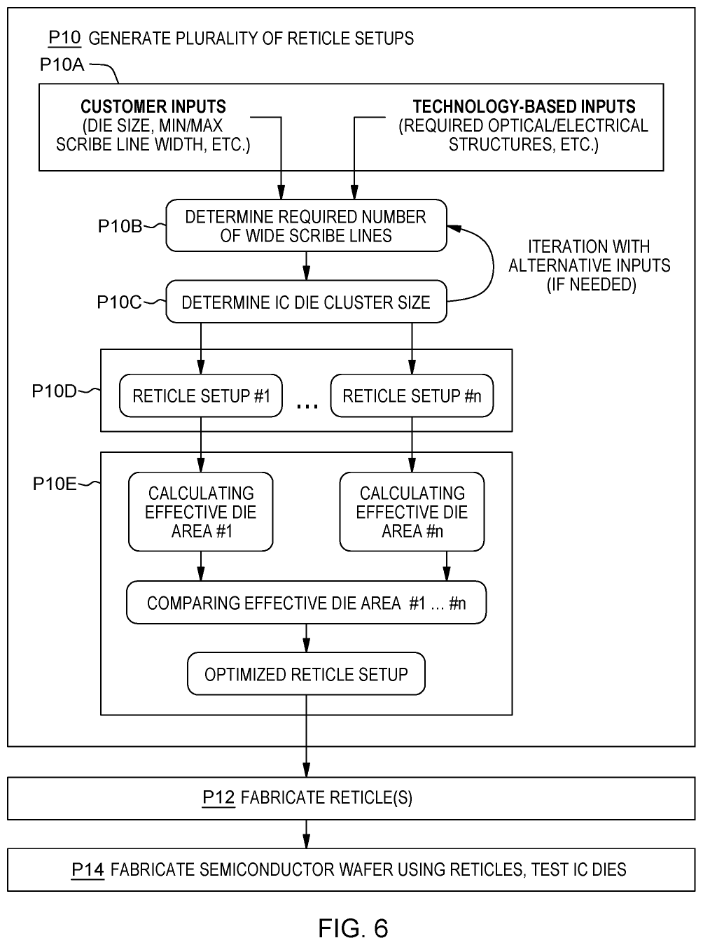

FIG. 6 shows a flow diagram of a method according to embodiments of the disclosure. With reference to FIGS. 4 and 6, in process P10, a plurality of reticle setups may be generated with each reticle setup representing a single-use reticle field arrangement and addressing a given set of design rules. As shown in process P10A, design rules can include those based on customer inputs such as IC die size, minimum and/or maximum scribe line width, among many others. Further, design rules can be based on technology-based inputs such as required optical and/or electrical test structures, among many others. In processes P10B and P10C, scribe line widths and cluster die size can be determined. In process P10B, a required number of wider scribe lines 140 can be defined, for example, based on the number, size, location and structural requirements of all of test structures 136 necessary for testing the desired IC dies 116. In process P10C, IC die cluster 130 size can be defined based on, for example, the area of field 112 of reticle(s) 100, the area of IC dies 116, and the required area of wider scribe lines 150 for test structures 136 (from process P10B). As shown by the arrow on the right side, generating the plurality of reticle setups, i.e., processes P10B and P10C, may be a repeated (reiteratively generating the setups) with each iteration changing a selected design rule and reducing the smallest effective die area. As used herein, “smallest effective die area” is area of the reticle (not the wafer) and is equal to the reticle area (reticle size in X direction times reticle size in Y direction) divided by the total number of usable dies (number of dies in X direction times number of dies in Y direction minus any sacrificial (stolen) dies). Hence, the smallest effective die area represents how efficient available area is used on reticle 100 (not wafer). In this manner, the most effective reticle 100 setup can be generated at the next process P10D that minimizes the wider scribe lines 150 and decreases effective die size to increase GDPW.

In process P10D, reticle setups addressing the design rules are generated based on the required number of wider scribe lines 150 and the IC die cluster size 130. At least one of the plurality of reticle 100 setups is based on a set of design rules that minimizes an area of the second scribe line 150 and accommodates all optical and electrical test structures 136 required for testing semiconductor wafer 122 in second scribe line 150. As previously described, each reticle 100 setup defines a layer including plurality of IC die clusters 130. Each of the IC die clusters 130 includes a plurality of IC dies 116 separated by first scribe line 140 having first width W1. IC die clusters 130 are arranged in juxtaposition to one another and are separated by second scribe line 150 having second width W2 larger than first width W1. IC die clusters 130 have a different number IC dies in an X direction than in a Y direction and each of the plurality of IC die clusters have the same area. In certain embodiments, where sufficient optimization is created through the design rules, a single reticle 100 setup may be generated that is optimized for use. Otherwise, different reticle 100 setups addressing the various design rules in different ways may be generated and further evaluated.

In optional processes P10E, where a plurality of reticle setups are generated in process P10D, additional evaluations can be carried out to identify the optimized reticle 100 setup, i.e., to identify the most effective reticle 100 setup that minimizes the wider scribe lines 150 and decrease effective die size to increase GDPW. In process P10E, an effective die area of each reticle setup generated in process P10D is calculated, and a comparison is performed to identify the reticle 100 setup that provides the smallest effective die area. The reticle 100 setup having the smallest effective die area is output as the optimized reticle setup.

Process P10 may be implemented using any appropriately programmed reticle design computer-based system, e.g., Mentor Graphics tool, Java, C++, etc. The details of such system are well known in the art and are not further described to focus the reader on the salient parts of the disclosure. Process P10 may be repeated for each reticle 100 required to fabricate semiconductor wafer 122 (FIG. 5).

In process P12, reticle 100 is fabricated including the reticle 100 setup of the plurality of reticle setups having a smallest effective die area. Reticle 100 can be fabricated using any now known or later developed techniques. The details of such processes are well known in the art and are not further described to focus the reader on the salient parts of the disclosure.

With reference to FIGS. 5 and 6, in process P14, semiconductor wafer 122 may be fabricated using any number of required reticles 100 (FIG. 4) fabricated according to the above-described methodology. That is, a plurality of the reticles 100 for different layers of IC dies 216 are used to form semiconductor wafer 122 including the plurality of IC dies 216. Semiconductor wafer 122 may be formed using any now known or later developed semiconductor fabrication techniques using reticles 100 (FIG. 4). As semiconductor fabrication techniques are well known in the art, no further details are necessary. Forming semiconductor wafer 122 includes forming at least part of an optical or electrical test structure 236 in an area of second scribe line 250. Any form of optical and/or electrical testing can be carried out with test structures 236. Use of die clusters 230 as described herein allows defect inspection in a manner not previously available for small dies. The usually applied defect inspection with die-to-die comparison identifies differences between corresponding (identical) locations of three (3) adjacent dies as a defect. This inspection requires across-wafer repeatability of the die and a minimum distance of corresponding locations between adjacent dies (i.e., equal die pitch). For too small die pitch and/or “steal die” approaches, as in FIG. 2 (with broken across-wafer repeatability) the workaround reticle-to-reticle comparison needs to be applied, leading to exclusion of all incomplete printed reticles from the inspection, like described relative to the conventional approach in FIG. 3. Using die clusters as described herein as “virtual die” for comparison provides a new across-wafer repeatability close to the technical optimum.

For example, in accordance with embodiments of the disclosure and with reference to FIG. 5, testing may include testing a first IC die 216A in first IC die cluster 230A by comparing first IC die 216A to second IC die 216B in second, different IC die cluster 230B. Because the IC dies 216A, 216B are intended to be identical, the comparison may identify differences across the wafer, improving across-wafer testing. In another example, testing may include testing a first IC die 216A in a selected IC die cluster 230A by comparing first IC die 216A to a second, different IC die 216C in the same, selected IC die cluster 230A. Because IC dies 216A, 216C are intended to be identical, the testing and comparison of IC dies 216 with a selected IC die cluster 230 provides very granular testing across and within semiconductor wafer 122.

IC dies 216 may be diced from semiconductor wafer 122 using any now known or later developed dicing techniques using two different width dicing tools for the different width scribe lines 140, 150, e.g., by a plasma cutter, blade or laser. As noted, the dicing removes and/or destroys test structures 236 from scribe lines 150.

Embodiments of the disclosure provide various technical and commercial advantages, examples of which are discussed herein. The reticle as described herein can be used to form a semiconductor wafer with increased GDPW. A semiconductor wafer with increased good dies is manufacturable without compromising quality, e.g., in terms of across reticle characterization, contamination-free manufacturing (CFM) die-to-die comparison, etc. The clustered die approach described herein is also highly scalable.

The structures and methods as described above are used in the fabrication of integrated circuit dies. The resulting integrated circuit dies can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A reticle, comprising:
a body having a single-use illumination field defined therein, the single-use illumination field defining a layer including:
a plurality of integrated circuit (IC) die clusters, each of the plurality of IC die clusters including a plurality of IC dies separated by a first scribe line having a first width,
wherein the plurality of IC die clusters are arranged in juxtaposition on the body and are separated by a second scribe line having a second width larger than the first width, and
wherein the plurality of IC die clusters each have a same number of IC dies and a same area.

2. The reticle of claim 1, wherein the layer of the single-use illumination field includes an optical or electrical test structure in an area of the second scribe line, and wherein the first scribe line is devoid of any optical or electrical test structure therein.

3. The reticle of claim 1, wherein the second scribe line extends around each of the plurality of IC die clusters individually.

4. The reticle of claim 1, wherein the second scribe line extends around collectively all of the plurality of IC die clusters.

5. The reticle of claim 1, wherein the plurality of IC die clusters includes at least three IC die clusters in an X direction, and a different number of IC die clusters in a Y direction.

6. A method, comprising:
generating a plurality of reticle setups, each reticle setup representing a single-use reticle field arrangement and addressing a given set of design rules, each reticle setup defining a layer including:
a plurality of integrated circuit (IC) die clusters, each of the plurality of IC die clusters including a plurality of IC dies separated by a first scribe line having a first width,
wherein the plurality of IC die clusters are arranged in juxtaposition to one another and are separated by a second scribe line having a second width larger than the first width, and
wherein the plurality of IC die clusters each have a same number of IC dies and a same area, and a different number of IC dies in an X direction than in a Y direction; and
fabricating a reticle including the reticle setup of the plurality of reticle setups having a smallest effective die area.

7. The method of claim 6, wherein generating the plurality of reticle setups includes reiteratively generating each of the plurality of reticle setups with each iteration changing a selected design rule and reducing the smallest effective die area.

8. The method of claim 6, wherein at least one of the plurality of reticle setups is based on a set of design rules that minimizes an area of the second scribe line and accommodates all optical and electrical test structures required for testing a semiconductor wafer in the second scribe line.

9. The method of claim 6, further comprising using a plurality of the reticles to form a semiconductor wafer including the plurality of IC dies.

10. The method of claim 9, wherein forming the semiconductor wafer includes forming at least part of an optical or electrical test structure in an area of the second scribe line.

11. The method of claim 9, wherein the second scribe line extends around collectively all of the plurality of IC die clusters.

12. The method of claim 9, wherein the plurality of IC die clusters includes at least three IC die clusters in an X direction, and a different number of IC die clusters in a Y direction.

13. The method of claim 9, further comprising testing a first IC die in a first IC die cluster by comparing the first IC die to a second IC die in a second, different IC die cluster.

14. The method of claim 9, further comprising testing a first IC die in a selected IC die cluster by comparing the first IC die to a second, different IC die in the selected IC die cluster.

15. A semiconductor wafer formed using the plurality of reticles according to claim 9.

16. A semiconductor wafer, comprising:
a plurality of integrated circuit (IC) die clusters, each of the plurality of IC die clusters including a plurality of IC dies separated by a first scribe line having a first width,
wherein the plurality of IC die clusters are arranged in juxtaposition and are separated by a second scribe line having a second width larger than the first width, and
wherein the plurality of IC die clusters each have a same number of IC dies and a same area, and a different number of IC dies in an X direction than in a Y direction.

17. The semiconductor wafer of claim 16, wherein all optical or electrical test structures are in an area of the second scribe line.

18. The semiconductor wafer of claim 16, wherein the second scribe line extends around each of the plurality of IC die clusters individually.

19. The semiconductor wafer of claim 16, wherein the second scribe line extends around collectively all of the plurality of IC die clusters.

20. The semiconductor wafer of claim 16, wherein the plurality of IC die clusters includes at least three IC die clusters in an X direction, and a different number of IC die clusters in a Y direction.
